(19) United States
(12) Patent Application Publication
(10) Pub. No.: US 2025/0364799 A1
(43) Pub. Date: Nov. 27, 2025

(54) DRIVING CIRCUIT, SIGNAL TRANSMISSION DEVICE, ELECTRONIC DEVICE, AND VEHICLE

(71) Applicant: ROHM CO., LTD., Kyoto-shi (JP)

(72) Inventors: Koki MISHIMA, Kyoto-shi (JP); Yasuhiro MIYAGOE, Kyoto-shi (JP)

(21) Appl. No.: 19/290,590

(22) Filed: Aug. 5, 2025

Related U.S. Application Data
(63) Continuation of application No. PCT/JP2023/046196, filed on Dec. 22, 2023.

(30) Foreign Application Priority Data
Feb. 7, 2023 (JP) 2023-016511

(51) Int. Cl. H02H 3/08; H03K 17/56

(52) U.S. Cl. CPC H02H 3/08; H03K 17/56

(57) ABSTRACT

For example, a driving circuit includes a short-circuit detection circuit that detects a short-circuit condition in which an excessive short-circuit current can pass through a switching device, and a controller that forcibly turns off the switching device on detecting a short-circuit condition. When forcibly turning off the switching device, the controller switches an output pulse signal for driving the switching device from a logic level (e.g., high level) corresponding to an on-period to a logic level (e.g., low level) corresponding to an off-period while reducing the slew rate stepwise.

### CROSS REFERENCE TO RELATED APPLICATIONS

This application is a continuation under 35 U.S.C. § 120 of International Patent Application No. PCT/JP2023/046196 filed on Dec. 22, 2023, which is incorporated herein by reference, and which claimed priority to Japanese Patent Application No. 2023-016511 filed on Feb. 7, 2023. The present application likewise claims priority under 35 U.S.C. § 119 to Japanese Application No. 2023-016511 filed on Feb. 7, 2023, the entire content of which is also incorporated herein by reference.

### TECHNICAL FIELD

The present disclosure relates to a driving circuit, a signal transmission device, an electronic device, and a vehicle.

### BACKGROUND ART

Today, signal transmission devices that transmit a signal between a primary circuit system and a secondary circuit system while isolating between them are used in a variety of applications (such as power supply devices and motor driving devices)

On example of known technology related to the above is seen in Patent Document 1 identified below by the present applicant

### CITATION LIST

### Patent Literature

Patent Document 1: JP 5926003 B2 (e.g., paragraph 0076)

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram showing a signal transmission device of a first embodiment.

FIG. 11 is a diagram showing one example of short-circuit detection operation in the first embodiment.

FIG. 12 is a diagram showing a signal transmission device of a second embodiment.

FIG. 13 is a diagram showing one example of short-circuit detection operation in the second embodiment.

FIG. 14 is a diagram showing the exterior appearance of a vehicle.

### DESCRIPTION OF EMBODIMENTS

### Signal Transmission Device (Basic Configuration)

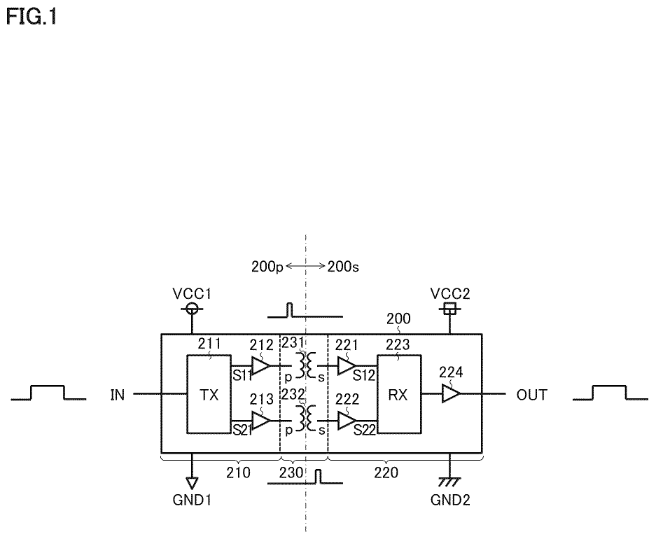

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCCI (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low- to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

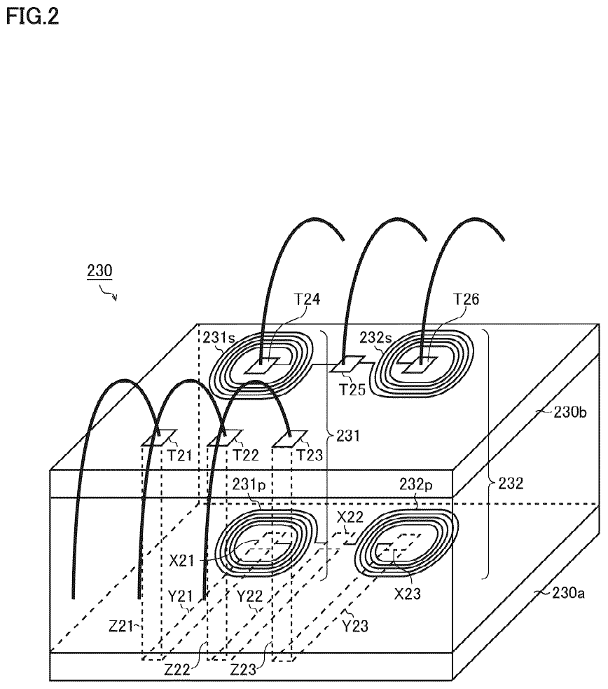

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### Transformer Chip (Two-Channel Type)

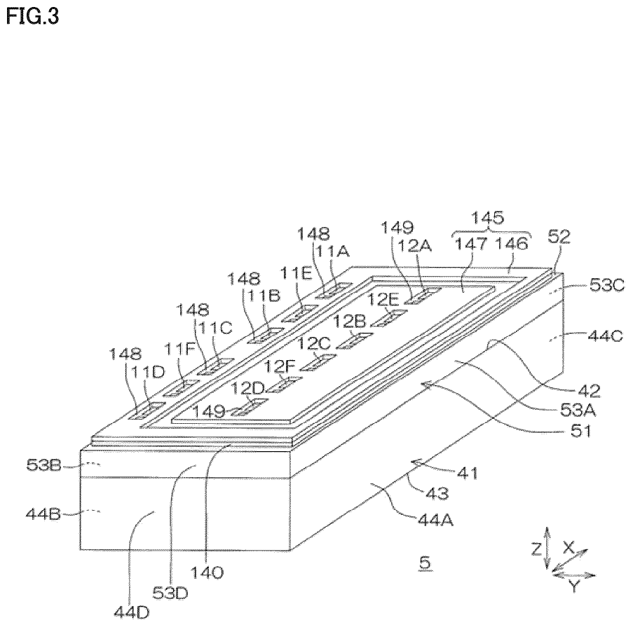

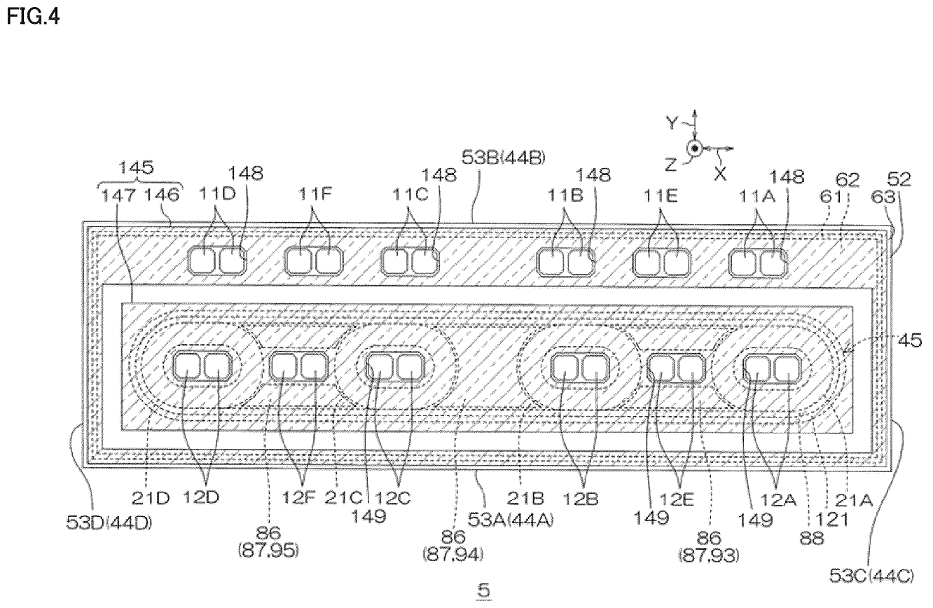

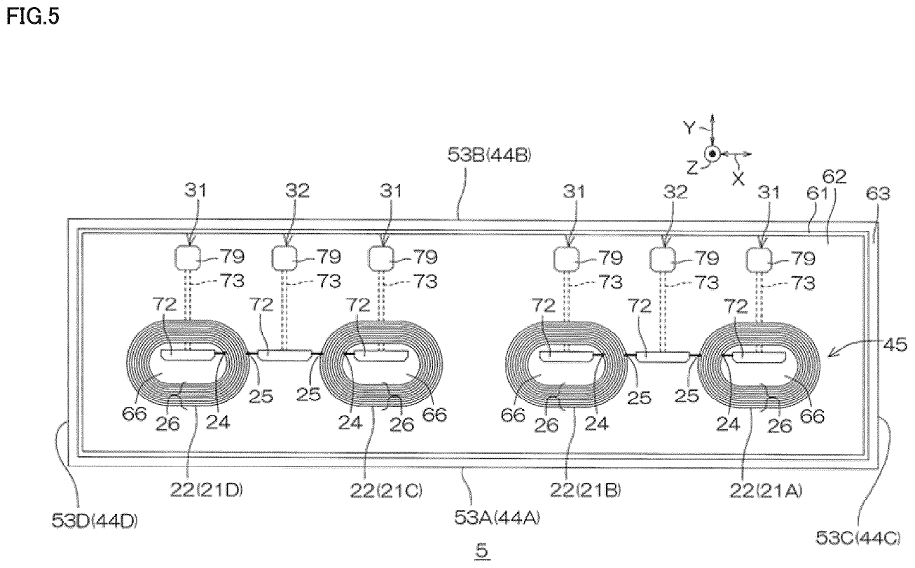

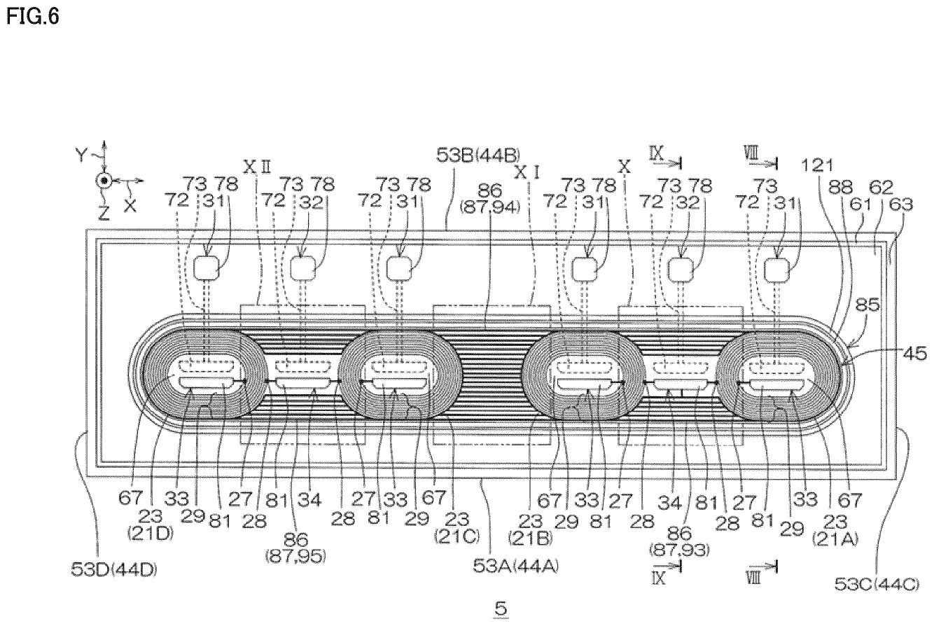

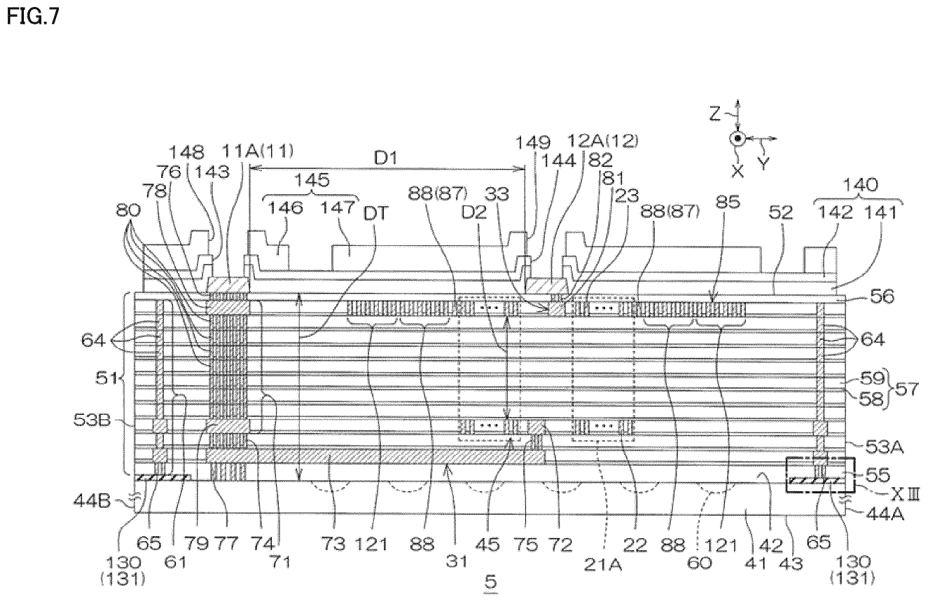

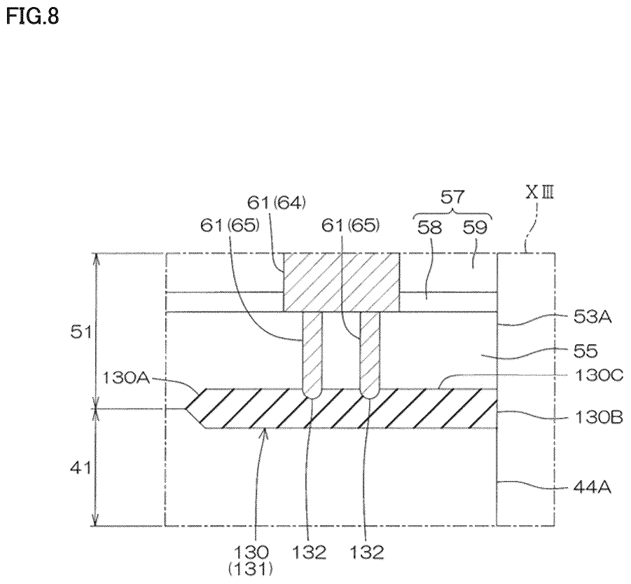

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low- and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low- and high-potential coils 22 and 23 can be disposed at any places. The high-potential coil 23 can face the low-potential coil 22 across one or more interlayer insulation layers 57.

The distance between the low- and high-potential coils 22 and 23 (i.e., the number of interlayer insulation layers 57 stacked together) is adjusted appropriately according to the dielectric strength voltage and electric field strength between the low- and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low- and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low- and high-potential terminals 11 and 12 is larger than the distance D2 between the low- and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high- and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low- and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low- and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a scaling conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The scaling conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the scaling conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of scaling plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped scaling conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of scaling via conductors 65 have a plane area smaller than the plane area of the scaling plug conductors 64. In a case where a single sealing via conductor 65 is formed, the single sealing via conductors 65 can have a plane area equal to or larger than the plane area of the scaling plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the scaling conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the scaling conductor 61 (i.e., the scaling via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low- and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low- and high-potential terminals 11 and 12, it is possible to suppress unnecessary conduction between the high-potential terminal 12 and the sealing conductor 61. Likewise, in a case where a voltage is applied to the second functional device 60 via the low- and high-potential terminals 11 and 12, it is possible to suppress unnecessary conduction between the low-potential terminal 11 and the sealing conductor 61.

The embodiment described above deals with an example where a second functional device 60 is formed. The second functional device 60, however, is not essential, and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

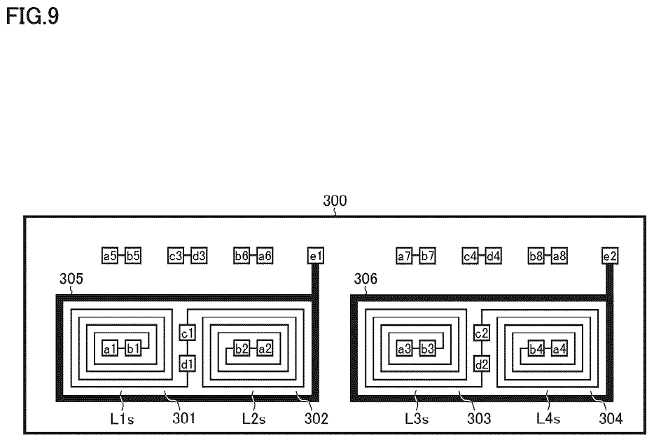

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and c2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Signal Transmission Device (First Embodiment)

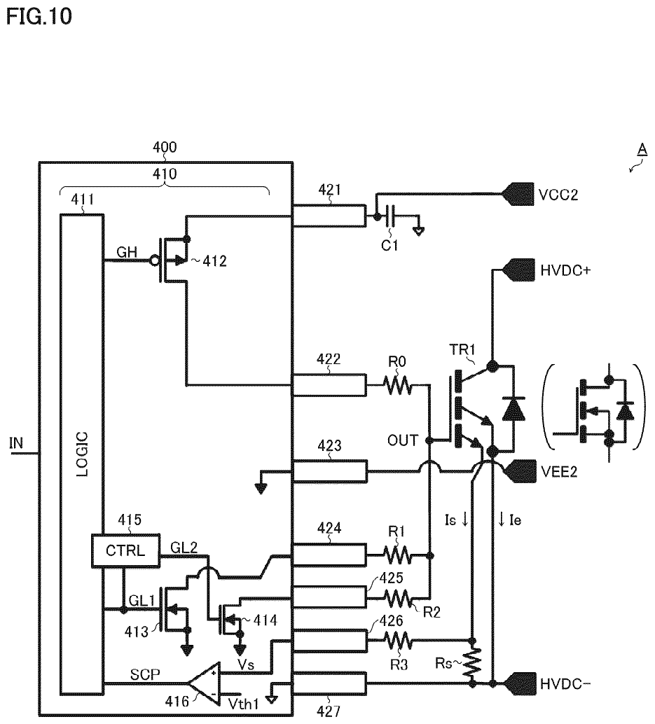

FIG. 10 is a diagram showing a signal transmission device 400 according to a first embodiment. The signal transmission device 400 of this embodiment is incorporated in an electronic device A along with various discrete components (a switching device TR1, resistors R0 to R3, a sense resistor Rs, and a capacitor C1).

The signal transmission device 400 is a semiconductor integrated circuit device (what is called an insulated-gate driver IC) that drives the switching device TR1 by generating according to an input pulse signal IN an output pulse signal OUT while isolating between input and output. The signal transmission device 400 includes, in particular as a means for driving the switching device TR1, a driving circuit 410.

Though not specifically illustrated in the diagram, the signal transmission device 400 can be, like the signal transmission device 200 described previously (FIG. 1), one having sealed in a single package a first chip (corresponding to the controller chip 210 described previously) that generates from the input pulse signal IN a transmission pulse signal, a second chip (corresponding to the driver chip 220 described previously) that generates from a reception pulse signal the output pulse signal OUT, and a third chip (corresponding to the transformer chip 230 described previously) that transmits the transmission pulse as the reception pulse while isolating between the first and second chips. In that case, the driving circuit 410 can be integrated in the second chip.

The signal transmission device 400 has, as a means for electrical connection with outside the device, external terminals 421 to 427. The external terminal 421 is a secondary power terminal (VCC2 pin). The external terminal 422 is a high-side output terminal (OUTH pin). The external terminal 423 is a negative power terminal (VEE2 pin). The external terminal 424 is a first low-side output terminal (OUTL pin). The external terminal 425 is a second low-side output terminal (PROOUT pin). The external terminal 426 is a current sense terminal (ISENSE pin). The external terminal 427 is a secondary ground terminal (GND2 pin).

The external terminal 421 is connected to an application terminal for a supply voltage VCC2 and to the first terminal of the capacitor C1. The second terminal of the capacitor C1 is connected to a reference potential terminal (e.g., a node HVDC−). The external terminal 422 is connected to the first terminal of the resistor R0. The external terminal 423 is connected to an application terminal for a negative supply voltage VEE2.

The external terminal 424 is connected to the first terminal of the resistor R1 (corresponding to a first external resistor). The external terminal 425 is connected to the first terminal of the resistor R2 (corresponding to a second external resistor). The resistor R2 can have a higher resistance value than the resistor R1. The external terminal 426 is connected to the first terminal of the resistor R3. The external terminal 427 is connected to the node HVDC−.

The switching device TR1 is a power transistor that switches between a conducting state and a shut-off state the path between a node HVDC+ and the node HVDC−. The switching device TR1 can be, for example, a high-side switching device and a low-side switching device in a half-bridge output stage or a full-bridge output stage. The half-bridge output stage or the full-bridge output stage can be used as a load driving means such as a motor driver or as a power conversion means such as an inverter.

As shown in the diagram, the switching device TR1 can be an IGBT. In that case, the collector of the switching device TR1 is connected to the node HVDC+. The first emitter of the switching device TR1 is connected to the node HVDC−. The second emitter (what is called an emitter sense) is connected to the first terminal of the sense resistor Rs and to the second terminal of the resistor R3. The second terminal of the sense resistor Rs is connected to the node HVDC−. The switching device TR1 is accompanied by a body diode having as its cathode and anode the collector and the first emitter, respectively, of the switching device TR1.

The gate of the switching device TR1 is connected to the respective second terminals of the resistors R0 to R2 (i.e., an application terminal for the output pulse signal OUT). That is, the external terminal 424 corresponds to a first external terminal that is connected via the resistor R1 to the application terminal for the output pulse signal OUT. On the other hand, the external terminal 425 corresponds to a second external terminal that is connected via the resistor R2, with a higher resistance value than the resistor R1, to the application terminal for the output pulse signal OUT.

As shown in parentheses in the diagram, the switching device TR1 can be replaced with a MOSFET (metal-oxide-semiconductor field-effect transistor). In that case, “collector” and “first emitter” in the above description can be read as “drain” and “source” respectively.

With reference still to FIG. 10, the internal configuration of the signal transmission device 400 (in particular, the driving circuit 410) will be described. The driving circuit 410 includes a logic circuit 411, a transistor 412 (e.g., PMOSFET), transistors 413 and 414 (e.g., NMOSFETs), a controller 415, and a short-circuit detection circuit 416 (e.g., comparator).

The logic circuit 411 generates the gate signals GH and GL1 for the transistors 412 and 413, respectively, according to the input pulse signal IN (more precisely, a reception pulse signal that is transmitted from a controller chip in an isolated fashion). The logic circuit 411 also has a function of detecting a short-circuit condition in a load (i.e., a faulty condition where an excessive current passes through the switching device TR1 due to a short circuit in the load), generating a fault signal FAULT (not shown in the diagram) to notify a controller chip (hence, an external device) of the condition.

The transistor 412 is a high-side switching device that together with the transistor 413 constitutes the half-bridge output stage of the driving circuit 410. The drain of the transistor 412 is connected to the external terminal 422. The source of the transistor 412 is connected to the external terminal 421. The external terminal 421 corresponds to an application terminal for an on-voltage for the switching device TR1 (i.e., the supply voltage VCC2). The on-voltage corresponds to the high level of the output pulse signal OUT, that is, the logic level corresponding to the on-period of the switching device TR1. The gate of the transistor 412 is connected to an application terminal for the gate signal GH. The transistor 412 is on when the gate signal GH is at low level; the transistor 412 is off when the gate signal GH is at high level.

The transistor 413 (corresponding to a first transistor) is a low-side switching device that together with the transistor 412 constitutes the half-bridge output stage of the driving circuit 410. The drain of the transistor 413 is connected to the external terminal 424. The source of the transistor 413 is connected to the external terminal 423. The external terminal 423 corresponds to an application terminal for the off-voltage for the switching device TR1 (i.e., the negative supply voltage VEE2). The off-voltage corresponds to the low level of the output pulse signal OUT, that is, the logic level corresponding to the off-period of the switching device TR1. The gate of the transistor 413 is connected to an application terminal for the gate signal GL1. The transistor 413 is on when the gate signal GL1 is at high level; the transistor 413 is off when the gate signal GL1 is at low level.

The transistor 414 (corresponding to a second transistor) is a second low-side switching device that is used for soft turn-off control on detection of a short circuit. The drain of the transistor 414 is connected to the external terminal 424. The source of the transistor 414 is, like the source of the transistor 413, connected to the external terminal 423 (i.e., the application terminal for the negative supply voltage VEE2, which corresponds to the off-voltage for the switching device TR1). The gate of the transistor 414 is connected to an application terminal for a gate signal GL2. The transistor 414 is on when the gate signal GL2 is at high level; the transistor 414 is off when the gate signal GL2 is at low level. Here, the transistor 414 can be one with a smaller device size and a higher on-resistance value than the transistor 413.

The controller 415 forcibly turns off the switching device TR1 when a short-circuit condition is detected in the load.

What is particular about the controller 415 is that, when it forcibly turns off the switching device TR1, it while reducing the slew rate stepwise turns the output pulse signal OUT from high level (the on-period logic level) to low level (the off-period logic level).

For example, the controller 415 can keep the slew rate at a first set value SR1 after the detection of the short-circuit condition in the load until a first time T1 elapses. The controller 415 can keep the slew rate at a second set value SR2 lower than the first set value SR1 after the lapse of the time T1 until a second time T2 elapses. At least one of the first and second times T1 and T2 can be variable.

In terms of what is shown in the diagram, after the detection of the short-circuit condition in the load until the first time T1 elapses, the controller 415 holds the transistor 413 on (GL1=H) and holds the transistor 414 off (GL2=L). As a result, the slew rate at a fall of the output pulse signal OUT is the first set value SR1 corresponding to the resistor R1.

Then, after the lapse of the time T1 until the second time T2 elapses, the controller 415 holds the transistor 413 off (GL1=L) and holds the transistor 414 on (GL2=H). As a result, the slew rate at a fall of the output pulse signal OUT is the second set value SR2 corresponding to the resistor R2. The resistor R2 has a higher resistance value than the resistor R1. Accordingly, the second set value SR2 is lower than the first set value SR1 mentioned above.

The controller 415 can be understood to be part of the logic circuit 411.

The short-circuit detection circuit 416 monitors a sense voltage Vs to generate, on detecting a short-circuit condition in the load, a short-circuit detection signal SCP. In terms of what is shown in the diagram, the short-circuit detection circuit 416 compares the sense voltage Vs applied to the short-circuit detection circuit 416 with a predetermined threshold voltage Vth1 to generate the short-circuit detection signal SCP.

The sense voltage Vs is a voltage signal (=Is×Rs) obtained by subjecting the sense current Is passing at the second emitter (emitter sense) of the switching device TR1 to I/V conversion with the sense resistor Rs. Here, the sense current Is is proportional to the output current Ie passing at the first emitter of the switching device TR1. Thus, the sense voltage Vs corresponds to a sense signal that corresponds to the output current Ie through the switching device TR1. That is, the sense voltage Vs increases as the output current Ie increases and decreases as the output current Ie decreases.

With the load in a normal condition (with no short circuit in it), no excessive current passes through the switching device TR1; thus the sense current Is too has a current value that falls within the expected range. The sense voltage Vs is set to be lower than the threshold voltage Vth1 in this condition. Accordingly, the short-circuit detection signal SCP has a logic level (e.g., low level) corresponding to no fault being detected.

By contrast, with the load in a short-circuit condition, an excessive short-circuit current passes through the switching device TR1 and thus the sense current Is increases beyond the expected range. This causes the sense voltage Vs to become higher than the threshold voltage Vth1. Accordingly, the short-circuit detection signal SCP has a logic level (e.g., high level) corresponding to a fault being detected.

As described above, the short-circuit detection circuit 416 employs, as a scheme for short-circuit detection for the load, what is called an emitter sense scheme. With the emitter sense scheme, by monitoring the sense voltage Vs it is possible to determine whether an excessive short-circuit current is passing through the switching device TR1, that is, whether the load is in a short-circuit condition.

### Short-Circuit Detection Operation (First Embodiment)

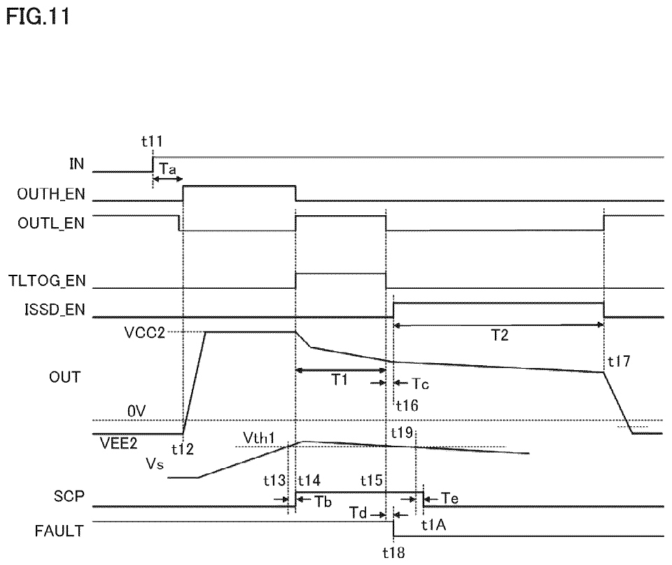

FIG. 11 is a diagram showing one example of short-circuit detection operation in the first embodiment The diagram depicts, from top down, the input pulse signal IN, a high-side output enable signal OUTH_EN, a low-side output enable signal OUTL_EN, a first short-circuit protection enable signal TLTOG_EN, a second short-circuit protection enable signal ISSD_EN, the output pulse signal OUT, the sense voltage Vs, the short-circuit detection signal SCP, and the fault signal FAULT.

The high-side and low-side output enable signals OUTH_EN and OUTL_EN can be understood as internal signals of the logic circuit 411. The first and second short-circuit protection enable signals TLTOG_EN and ISSD_EN can be understood as internals signals of the controller 415.

At time t11, the input pulse signal IN is raised to high level. After that, at time t12, the high-side output enable signal OUTH_EN is raised to high level and the low-side output enable signal OUTL_EN is dropped to low level. Now, the transistor 412 is on and the transistors 413 and 414 are both off. As a result, the output pulse signal OUT rises from low level (=VEE2<0 V) up to high level (=VCC2). The period between times t11 and t12 corresponds to the signal transmission time Ta from the controller chip to the driver chip.

At time t13, as the output current Ie (hence the sense current Is) increases due to a short circuit in the load, the sense voltage Vs becomes higher than the threshold voltage Vth1. In response, at time the 14, the short-circuit detection signal SCP is raised to high level (the logic level corresponding to a fault being detected). The period between times t13 and t14 corresponds to the internal processing time Tb of the short-circuit detection circuit 416.

At time t14, in response to the short-circuit detection signal SCP rising, the high-side output enable signal OUTH_EN is dropped to low level and the low-side output enable signal OUTL_EN is raised to high level. Now, the transistor 412 is off and one of the transistors 413 and 414 is on.

Between times t14 and t15, over the first time T1, the first short-circuit protection enable signal TLTOG_EN is held at high level and the second short-circuit protection enable signal ISSD_EN is kept at low level. During this time, the transistor 413 is held on and the transistor 414 is kept off. That is, the slew rate at a fall of the output pulse signal OUT is set to the first set value SR1 (high slew rate). As a result, the output pulse signal OUT falls more sharply than during the second time T2 (between times t16 and t17), which will be described later.

After the lapse of the first time T1, between times t16 and t17, over the second time T2, the first short-circuit protection enable signal TLTOG_EN is held at low level and the second short-circuit protection enable signal ISSD_EN is held at high level. During this time, the transistor 413 is held off and the transistor 414 is held on. That is, the slew rate at a fall of the output pulse signal OUT is switched to the second set value SR2 (low slew rate). As a result, the output pulse signal OUT falls more gently than during the first time T1 (between times t14 and t15) mentioned above. The period between times t15 and t16 corresponds to the simultaneous-on prevention period Tc for the transistors 413 and 414.

As described above, in the signal transmission device 400 (in particular, the driving circuit 410) of this embodiment, on detection of a short-circuit condition in the load, two-stage soft turn-off control is performed.

At the first stage (T1), the output pulse signal OUT is lowered at a comparatively high slew rate. Thus, the on-state resistance value of the switching device TR1 increases without delay. This quickly suppresses the excessive short-circuit current through the switching device TR1.

At the second stage (T2), the output pulse signal OUT is lowered at a comparatively low slew rate. This permits the switching device TR1 to be turned off gently and suppresses an excessive voltage surge (i.e., a hike in voltage due to di/dt).

Consider control without the first stage (T1), that is, control that lowers the output pulse signal OUT at a constant low slew rate as at the second stage (T2). With this control, over the entire period after the detection of a short circuit in the load during which soft turn-off control is performed for the switching device TR1, the output current Ie through the switching device TR1 decreases gently. This can result in an increased power loss in the switching device TR1.

By contrast, with two-stage soft turn-off control, first, at the first stage (T1), the output current Ie is suppressed quickly and then, at the second stage (T2), a switch is made to the suppression of a voltage surge. This can achieve voltage surge suppression combined with loss reduction.

The first and second times T1 and T2 can be set as desired by use of a timer. The first and second set vales SR1 and SR2 of the slew rate can be adjusted as desired with the externally connected resistors R1 and R2.

After the lapse of the second stage (T2), at time t17, the low-side output enable signal OUTL_EN is raised to high level. Now the transistor 413 is on. Thus, the output pulse signal OUT falls more sharply than at the second stage (T2).

After the completion of the first stage (T1), at time t18, the fault signal FAULT is dropped to low level (the logic level corresponding to a fault being detected). Through signal processing as described above, the occurrence of a fault is communicated to outside the signal transmission device 400. The period between times t15 to t18 corresponds to the internal processing time Td of the logic circuit 411. The timing with which the logic level of the fault signal FAULT is switched is not limited to as described above. For example, the fall of the short-circuit detection signal SCP at time t14 can be taken as a trigger to drop the logic level of the fault signal FAULT to low level.

At time t19, as the output current Ie is suppressed, the sense voltage Vs becomes lower than the threshold voltage Vth1. In response, at time t1A, the short-circuit detection signal SCP is dropped to low level (the logic level corresponding to no fault being detected). The period between times t19 to t1A corresponds to the internal processing time Te of the short-circuit detection circuit 416.

### Signal Transmission Device (Second Embodiment)

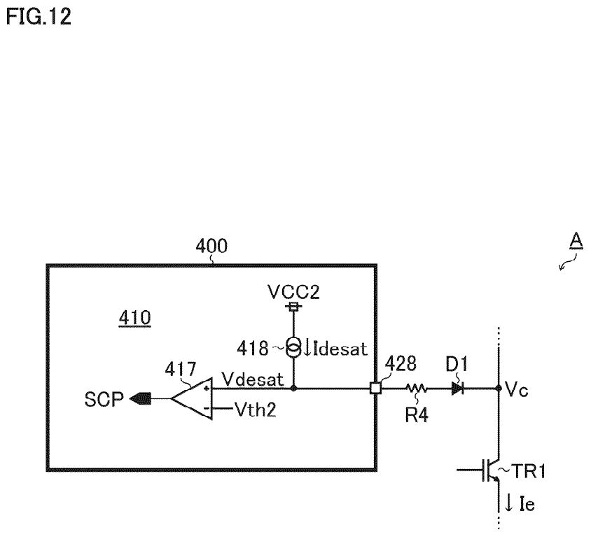

FIG. 12 is a diagram showing a signal transmission device 400 according to a second embodiment. The signal transmission device 400 of this embodiment is based on the first embodiment (FIG. 10) described previously but employs a modified scheme for short-circuit detection. In terms of what is shown in the diagram, in this embodiment, a driving circuit 410 includes, instead of the short-circuit detection circuit 416 and the external terminal 426 described previously, a short-circuit detection circuit 417 (e.g., comparator), a current source 418, and an external terminal 428. The diagram further shows, as discrete components that are externally connected to the signal transmission device 400, a resistor R4 and a diode D1.

The external terminal 428 is a desaturation detection terminal (DESUT pin). The external terminal 428 is connected to the first terminal of the resistor R4. The second terminal of the resistor R4 is connected to the anode of the diode D1. The cathode of the diode D1 is connected to the collector of the switching device TR1 (i.e., an application terminal for a collector voltage Vc).

The short-circuit detection circuit 417 monitors desaturation between the collector and the emitter of the switching device TR1 and thereby detects a short-circuit condition in the load to generate a short-circuit detection signal SCP. In terms of what is shown in the diagram, the short-circuit detection circuit 417 generates the short-circuit detection signal SCP by comparing a desaturation detection voltage Vdesat applied to the external terminal 428 with a predetermined threshold voltage Vth2.

The current source 418 is connected between an application terminal for a supply voltage VCC2 and the external terminal 428 and generates a bias current Idesat.

With the load in a normal condition (a condition with no short circuit), the collector voltage Vc of the switching device TR1 is nearly 0 V (i.e., the application voltage at the node HVDC−), and thus the diode D1 is reverse-biased. Accordingly, the bias current Idesat passes from the current source 418 via the resistor R4 and the diode D1. The desaturation detection voltage Vdesat (=Idesat×R4+Vf+Vc, where Vf is the forward drop voltage across the diode D1) is set to be lower than the threshold voltage Vth2 in this condition. Accordingly, the short-circuit detection signal SCP has a logic level (e.g., low level) corresponding to no fault being detected.

On the other hand, with the load in a short-circuit condition, an excessive short-circuit current passes through the switching device TR1 and thus the collector voltage Vc of the switching device TR1 rises beyond the expected range. Now, the desaturation detection voltage Vdesat is higher than the threshold voltage Vth2. Accordingly, the short-circuit detection signal SCP has a logic level (e.g., high level) corresponding to a fault being detected.

As described above, the short-circuit detection circuit 417 employs, as a scheme for short-circuit detection for the load, what is called a DESAT scheme. With the DESAT scheme, by monitoring desaturation between the collector and the emitter of the switching device TR1 it is possible to detect whether an excessive short-circuit current is passing through the switching device TR1, that is, whether the load is in a short-circuit condition.

### Short-Circuit Detection Operation (Second Embodiment)

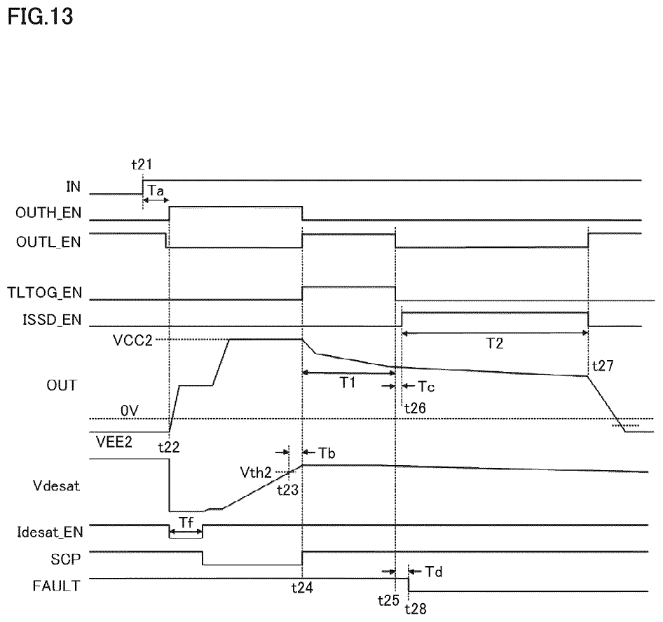

FIG. 13 is a diagram showing one example of short circuit detection operation in the second embodiment. The diagram depicts, from top down, the input pulse signal IN, the high-side output enable signal OUTH_EN, the low-side output enable signal OUTL_EN, the first short-circuit protection enable signal TLTOG_EN, the second short-circuit protection enable signal ISSD_EN, the output pulse signal OUT, the desaturation detection voltage Vdesat, a bias current enable signal Idesat_EN, the short-circuit detection signal SCP, and the fault signal FAULT.

The high-side and low-side output enable signals OUTH_EN and OUTL_EN can be understood to be internal signals of the logic circuit 411. The first and second short-circuit protection enable signals ISSD_EN and TLTOG_EN and the bias current enable signal Idesat_EN can be understood to be internal signals of the controller 415.

At time t21, the input pulse signal IN is raised to high level. After that, at time t22, the high-side output enable signal OUTH_EN is raised to high level and the low-side output enable signal OUTL_EN is dropped to low level. Now, the transistor 412 is on and the transistors 413 and 414 are both off. As a result, the output pulse signal OUT rises from low level (=VEE2<0 V) up to high level (=VCC2). The period between times t21 and t22 corresponds to the signal transmission time Ta from the controller chip to the driver chip.

After time t21 until a predetermined standby time Tf elapses, the bias current enable signal Idesat_EN is held at low level. During this period, the bias current Idesat is not generated. Accordingly, the desaturation detection voltage Vdesat is kept at 0 V.

After that, when the standby time Tf elapses, the bias current enable signal Idesat_EN is raised to high level so that the bias current Idesat starts to be generated. As a result, the desaturation detection voltage Vdesat rises.

At time t23, as the output current Ie increases due to a short circuit in the load, the desaturation detection voltage Vdesat becomes higher than the threshold voltage Vth2. In response, at time t24, the short-circuit detection signal SCP is raised to high level (i.e., the logic level corresponding to a fault being detected). The period between times t23 and t24 corresponds to the internal processing time Tb of the short-circuit detection circuit 417.

After time t24, in a similar manner as described above, two-stage soft turn-off control is performed. To minimize repetition, this can be briefly described as follows. First, at the first stage (T1) between times t24 and t25, the output pulse signal OUT is lowered at a comparatively high slew rate (SR1). As a result, at the first stage (T1), the excessive short-circuit current passing through the switching device TR1 is suppressed quickly.

After that, at the second stage (T2) between times t26 and t27, the output pulse signal OUT is lowered at a comparatively low slew rate (SR2). As a result, at the second stage (T2), the switching device TR1 is turned off gently, and this effectively suppresses a voltage surge.

### Application in Vehicles

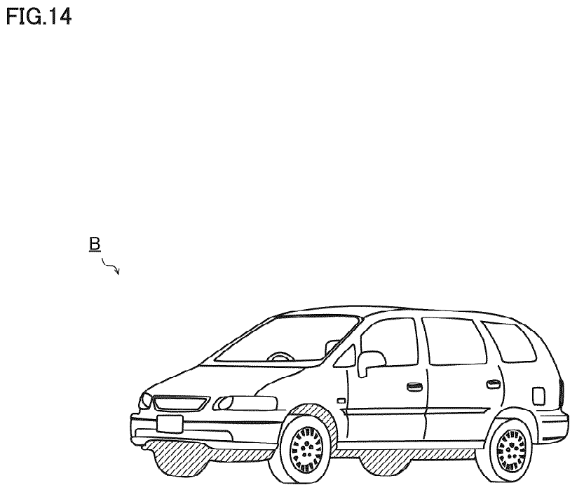

FIG. 14 is a diagram showing the exterior appearance of a vehicle. The vehicle B of this configuration example incorporates various electronic devices that operate by being supplied with electric power from a battery.

The vehicle B can be an engine vehicle, or an electric vehicle (xEV such as BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle].

The signal transmission device 200 or 400 described previously can be built in any of the electronic devices incorporated in the vehicle B.

### Overview

According to the present disclosure, it is possible to provide a driving circuit that can achieve voltage surge suppression combined with loss reduction in soft turn-off control on detection of a short circuit, and to provide a signal transmission device, an electronic device, and a vehicle provided with such a driving circuit. To follow is an overview of the various embodiments disclosed herein.

For example, according to one aspect of what is disclosed herein, a driving circuit includes: a short-circuit detection circuit configured to detect a short-circuit condition in which an excessive short-circuit current can pass through a switching device; and a controller configured to forcibly turn off the switching device on detecting the short-circuit condition. When forcibly turning off the switching device, the controller switches an output pulse signal for driving the switching device from a logic level corresponding to an on-period to a logic level corresponding to an off-period while reducing a slew rate stepwise. (A first configuration.)

In the driving circuit of the first configuration described above, after the short-circuit condition is detected until a first predetermined time elapses, the controller can hold the slew rate at a first set value, and after the first predetermined time has elapsed until a predetermined second time elapses, the controller can hold the slew rate at a second set value lower than the first set value. (A second configuration.)

In the driving circuit of the second configuration described above, at least one of the first and second times can be variable. (A third configuration.)

The driving circuit of the second or third configuration described above can further include: a first external terminal configured to be connected via a first external resistor to an application terminal for the output pulse signal; a second external terminal configured to be connected via a second external resistor with a higher resistance value than the first external resistor to the application terminal for the output pulse signal; a first transistor connected between the first external terminal and an application terminal for an off-voltage corresponding to the logic level corresponding to the off-period; and a second transistor connected between the second external terminal and the application terminal for the off-voltage. After the short-circuit condition is detected until the first time elapses, the controller can hold the first transistor on and hold the second transistor off, and after the first time has elapsed until the second time elapses, the controller can hold the first transistor off and hold the first transistor on. (A fourth configuration.)

In the driving circuit of any of the first to fourth second configurations described above, the short-circuit detection circuit can monitor a sense signal corresponding to the output current that passes through the switching device. (A fifth configuration.)

In the driving circuit of any of the first to fourth second configurations described above, the short-circuit detection circuit can monitor the desaturation state across terminals of the switching device. (A sixth configuration.)

The driving circuit of any of the first to sixth second configurations described above can further include a logic circuit configured to generate a fault signal for indicating the short-circuit condition. (A seventh configuration.)

For example, according to another aspect of what is disclosed herein, a signal transmission device has sealed in a single package: a first chip configured to generate from an input pulse signal a transmission pulse signal; a second chip configured to generate from a reception pulse signal an output pulse signal; and a third chip configured to transmit the transmission pulse signal as the reception pulse signal while isolating between the first and second chips. The second chip has integrated in it the driving circuit according to any of the first to seventh configurations described above. (An eighth configuration.)

For example, according to another aspect of what is disclosed herein, an electronic device includes: the signal transmission device according to the eighth configuration described above; and the switching device configured to be driven by the driving circuit. (A ninth configuration.)

For example, according to another aspect of what is disclosed herein, a vehicle includes the electronic device of the ninth configuration described above. (A tenth configuration.)

### Notes

The various technical features disclosed in the present description can be implemented in any manner other than as specifically described above and allow for various modifications without departure from the spirit of their technical ingenuity. That is, the embodiments described above should be taken to be in every aspect illustrative and not restrictive. The technical scope of the present disclosure should be understood to be defined by the appended claims and to encompass any variations within a scope equivalent in significance to the scope of those claims.

1. A driving circuit comprising:
a short-circuit detection circuit configured to detect a short-circuit condition in which an excessive short-circuit current can pass through a switching device; and
a controller configured to forcibly turn off the switching device on detecting the short-circuit condition,
wherein
when forcibly turning off the switching device, the controller switches an output pulse signal for driving the switching device from a logic level corresponding to an on-period to a logic level corresponding to an off-period while reducing a slew rate stepwise.

2. The driving circuit according to claim 1, wherein
after the short-circuit condition is detected until a first predetermined time elapses, the controller holds the slew rate at a first set value, and
after the first predetermined time has elapsed until a predetermined second time elapses, the controller holds the slew rate at a second set value lower than the first set value.

3. The driving circuit according to claim 2 wherein
at least one of the first and second times is variable.

4. The driving circuit according to claim 2, further comprising:
a first external terminal configured to be connected via a first external resistor to an application terminal for the output pulse signal;
a second external terminal configured to be connected via a second external resistor with a higher resistance value than the first external resistor to the application terminal for the output pulse signal;
a first transistor connected between the first external terminal and an application terminal for an off-voltage corresponding to the logic level corresponding to the off-period; and
a second transistor connected between the second external terminal and the application terminal for the off-voltage,
wherein
after the short-circuit condition is detected until the first time elapses, the controller holds the first transistor on and holds the second transistor off, and
after the first time has elapsed until the second time elapses, the controller holds the first transistor off and holds the first transistor on.

5. The driving circuit according to claim 1, wherein
the short-circuit detection circuit monitors a sense signal corresponding to an output current that passes through the switching device.

6. The driving circuit according to claim 1, wherein
the short-circuit detection circuit monitors a desaturation state across terminals of the switching device.

7. The driving circuit according to claim 1, further comprising a logic circuit configured to generate a fault signal for indicating the short-circuit condition.

8. A signal transmission device having sealed in a single package:
a first chip configured to generate from an input pulse signal a transmission pulse signal;
a second chip configured to generate from a reception pulse signal an output pulse signal; and
a third chip configured to transmit the transmission pulse signal as the reception pulse signal while isolating between the first and second chips,
wherein
the second chip has the driving circuit according to claim 1 integrated in it.

9. An electronic device comprising:
the signal transmission device according to claim 8; and
the switching device configured to be driven by the driving circuit.

10. A vehicle comprising the electronic device according to claim 9.
